(19) United States
(12) Patent Application Publication
(10) Pub. No.: US 2024/0420953 A1
(43) Pub. Date: Dec. 19, 2024

(54) SYSTEMS AND METHODS FOR IMPROVING MECHANICAL STRENGTH OF LOW DIELECTRIC CONSTANT MATERIALS

(71) Applicant: Applied Materials, Inc., Santa Clara, CA (US)

(72) Inventors: Rui Lu, Santa Clara, CA (US); Bo Xie, San Jose, CA (US); Wei Liu, Fremont, CA (US); Shanshan Yao, San Jose, CA (US); Xiaobo Li, San Jose, CA (US); Jingmei Liang, San Jose, CA (US); Li-Qun Xia, Cupertino, CA (US); Shankar Venkataraman, San Jose, CA (US); Chi-I Lang, Cupertino, CA (US)

(73) Assignee: Applied Materials, Inc., Santa Clara, CA (US)

(21) Appl. No.: 18/209,719

(22) Filed: Jun. 14, 2023

(51) Int. Cl. H01L 21/02

(52) U.S. Cl. CPC H01L 21/0234; H01L 21/02348

(57) ABSTRACT

Exemplary processing methods may include providing a treatment precursor to a processing region of a semiconductor processing chamber. A substrate may be housed within the processing region. The substrate may include a layer of a silicon-containing material. The methods may include forming inductively-coupled plasma effluents of the treatment precursor. The methods may include contacting the layer of the silicon-containing material with the inductively-coupled plasma effluents of the treatment precursor to produce a treated layer of the silicon-containing material. The contacting may reduce a dielectric constant of the layer of the silicon-containing material.

### TECHNICAL FIELD

The present technology relates to semiconductor processing. More specifically, the present technology relates methods of producing low dielectric constant (K) materials with improved mechanical strength.

### BACKGROUND

Integrated circuits are made possible by processes which produce intricately patterned material layers on substrate surfaces. Producing patterned material on a substrate requires controlled methods for forming and removing material. Material characteristics may affect how the device operates, and may also affect how the materials are removed relative to one another. Plasma-enhanced deposition may produce materials having certain characteristics. Many materials that are formed require additional processing to adjust or enhance characteristics of the material in order to provide suitable properties.

Thus, there is a need for improved systems and methods that can be used to produce high quality devices and structures. These and other needs are addressed by the present technology.

### SUMMARY

Exemplary processing methods may include providing a treatment precursor to a processing region of a semiconductor processing chamber. A substrate may be housed within the processing region. The substrate may include a layer of a silicon-containing material. The methods may include forming inductively-coupled plasma effluents of the treatment precursor. The methods may include contacting the layer of the silicon-containing material with the inductively-coupled plasma effluents of the treatment precursor to produce a treated layer of the silicon-containing material. The contacting may reduce a dielectric constant of the layer of the silicon-containing material.

In some embodiments, the treatment precursor may be or include one or more of diatomic nitrogen (N₂), diatomic oxygen (O₂), ammonia (NH₃), argon (Ar), helium (He), or diatomic hydrogen (H₂). The silicon-containing material may be a silicon-and-oxygen-containing material, a silicon-carbon-and-oxygen-containing material, or a silicon-carbon-oxygen-and-hydrogen-containing material. The inductively-coupled plasma effluents of the treatment precursor may be formed at a plasma power of greater than or about 2,000 W. The treated layer of the silicon-containing material may be characterized by a dielectric constant of less than or about 2.9. The contacting may increase Si—C—Si crosslinking in the layer of the silicon-containing material. The treated layer of the silicon-containing material may be characterized by Si—C—Si crosslinking of greater than or about 0.4%. Contacting the layer of the silicon-containing material with the inductively-coupled plasma effluents of the treatment precursor may reduce a carbon content in the layer of the silicon-containing material. A pressure within the processing region may be maintained at less than or about 50 Torr. A temperature within the processing region may be maintained at greater than or about 150° C. The methods may include exposing the treated layer of the silicon-containing material to ultraviolet light to produce a cured layer of the silicon-containing material.

Some embodiments of the present technology may encompass semiconductor processing methods. The methods may include providing a treatment precursor to a processing region of a semiconductor processing chamber. A substrate may be housed within the processing region. The substrate may include a layer of a silicon-containing material. The methods may include forming inductively-coupled plasma effluents of the treatment precursor at a plasma power of greater than or about 2,000 W. The methods may include contacting the layer of the silicon-containing material with the inductively-coupled plasma effluents of the treatment precursor to produce a treated layer of the silicon-containing material. The contacting may increase one or more mechanical properties of the layer of the silicon-containing material.

In some embodiments, the silicon-containing material may be a silicon-and-oxygen-containing material, a silicon-carbon-and-oxygen-containing material, or a silicon-carbon-oxygen-and-hydrogen-containing material. The one or more mechanical properties may include hardness, Young's modulus, dielectric constant, or porosity. The treated layer of the silicon-containing material may be characterized by a second thickness less than a first thickness of the layer of the silicon-containing material. The methods may include exposing the treated layer of the silicon-containing material to ultraviolet light to produce a cured layer of the silicon-containing material. The exposing may reduce a methyl concentration in the layer of the treated layer of the silicon-containing material. The cured layer of the silicon-containing material may be characterized by a methyl concentration of less than or about 4.5%. The cured layer of the silicon-containing material may be characterized by a dielectric constant of less than or about 2.85. The cured layer of the silicon-containing material may be characterized by a hardness of greater than or about 3 GPa.

Some embodiments of the present technology may encompass semiconductor processing methods. The methods may include providing a treatment precursor to a processing region of a semiconductor processing chamber. A substrate may be housed within the processing region. The substrate may include a layer of a silicon-containing material. The methods may include forming inductively-coupled plasma effluents of the treatment precursor. The methods may include contacting the layer of the silicon-containing material with the inductively-coupled plasma effluents of the treatment precursor to produce a treated layer of the silicon-containing material. The methods may include exposing the treated layer of the silicon-containing material to ultraviolet light to produce a cured layer of the silicon-containing material.

In some embodiments, the treatment precursor may be or include helium (He). The cured layer of the silicon-containing material may be characterized by a hardness of greater than or about 2 GPa.

Such technology may provide numerous benefits over conventional systems and techniques. For example, by performing the treatment and/or UV light exposure to the layer of the silicon-containing material, desirable properties can be obtained. Additionally, the treatment and/or UV light exposure may break the conventional tradeoff commonly associated with dielectric constant and mechanical strength. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of an exemplary plasma processing apparatus according to some embodiments of the present technology.

FIG. 2 shows a schematic cross-sectional view of an exemplary plasma processing apparatus according to some embodiments of the present technology.

FIG. 3 shows a schematic cross-sectional view of an exemplary plasma processing apparatus according to some embodiments of the present technology.

FIG. 4 shows a schematic cross-sectional view of an exemplary plasma processing apparatus according to some embodiments of the present technology.

FIG. 5 shows a schematic cross-sectional view of an exemplary plasma processing apparatus according to some embodiments of the present technology.

FIG. 6 shows an isometric view of an exemplary induction coil according to some embodiments of the present technology.

FIG. 7 shows exemplary operations in a processing method according to some embodiments of the present technology.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

During back-end-of-line (BEOL) semiconductor processing, low-K materials may serve multiple functions in the fabrication of metallization layers in an integrated circuit. These functions may include the incorporation of electrically-insulating low-K materials between electrically-conductive metal-containing structures such as interconnect lines, contact holes, and vias, among other structures. They may also include the partial removal of a low-K material following the formation of metal structure. One common removal process in BEOL processing is chemical-mechanical-polishing (CMP) that uses a combination of chemical etching and physical abrasion to remove the low-k material from a substrate surface.

Low-K materials used in BEOL processing should have a low dielectric constant relative to undoped silicon oxide and high mechanical stability to resist fracturing during the formation of metal-containing structures and removal by CMP. Unfortunately, these qualities are often in tension in low-K materials made from a UV-treated silicon-carbon-and-oxygen-containing material. In many instances, the UV treatment increases the porosity of the material, and the increased porosity can reduce the material's mechanical stability. In addition, the increased levels of carbon in the material may both lower the k value and reduce the material's mechanical stability. The reduction in mechanical stability may be measured by the material having a lower hardness and a lower Young's modulus, among the material's other mechanical characteristics.

One approach to addressing these issues is to replace the UV treatment operation with other types of treatments. In some conventional embodiments, a UV treatment operation is eliminated by depositing the low-K material at increased deposition temperatures, such as greater than or about 500° C. Unfortunately, these higher deposition temperatures can exceed the thermal budgets of many semiconductor fabrication processes. The higher temperatures can also create unwanted reactions in the depositing low-K material, such as the reaction of Si—H and oxygen groups to form hydroxyl groups (—OH) in the as-deposited material. Relatively small amounts of hydroxyl groups can significantly increase the dielectric constant of a low-K material. In additional conventional methods, a UV treatment operation is replaced with a plasma treatment following the deposition of the low-K material. While plasma treatments may be conducted at lower temperatures than high-temperature depositions, they are generally conducted at higher temperatures than UV treatments, such as greater than or about 400° C. These plasma treatment temperatures can put a strain on the thermal budgets of some semiconductor fabrication methods.

The present technology may overcome these issues by including embodiments of semiconductor processing methods that form treated, low-K materials with increased mechanical stability. With an optional UV treatment, these treated low-K materials may be characterized by a dielectric constant of less than or about 3.8. However, unlike conventional technologies, embodiments of the present technology may maintain the mechanical stability of the materials despite the reduced dielectric constant. The materials may be characterized by a high hardness of greater than or about 2 GPa, as well as a high Young's modulus of greater than or about 4 GPa.

After describing general aspects of a chamber according to some embodiments of the present technology in which processing operations discussed below may be performed, specific methodology may be discussed. It is to be understood that the present technology is not intended to be limited to the specific materials, chambers or processes discussed, as the techniques described may be used to improve a number of material formation processes, and may be applicable to a variety of processing chambers and operations.

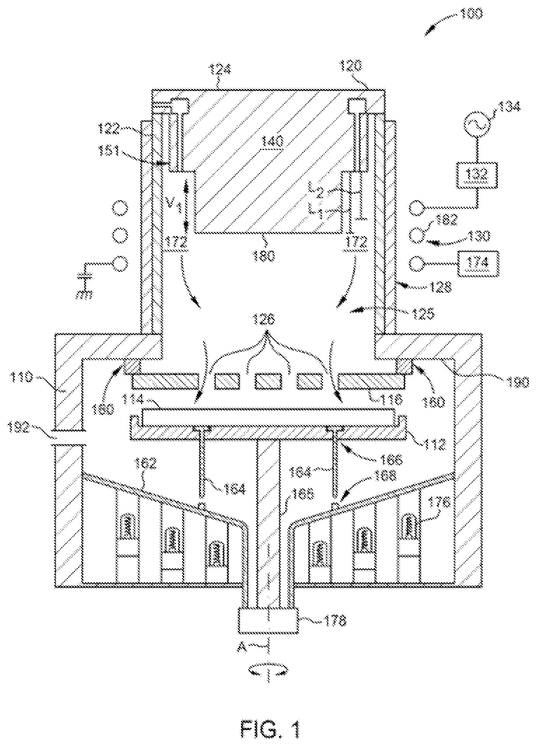

FIG. 1 shows a cross-sectional view of an exemplary plasma processing apparatus 100 according to some embodiments of the present technology. The figure may illustrate an overview of a system incorporating one or more aspects of the present technology, and/or which may perform one or more deposition or other processing operations according to embodiments of the present technology. Additional details of plasma processing apparatus 100 or methods performed may be described further below. The plasma processing apparatus 100 may include a processing chamber 110 and a plasma source 120 coupled with the processing chamber 110. The processing chamber 110 may include includes a substrate support 112 operable to hold a substrate 114. In embodiments, the substrate has a thickness that is less than about 1 mm. Substrate support 112 can be proximate one or more heat sources (for example, a plurality of lamps 176) that provide heat to a substrate during processing of the substrate in the processing chamber 110. Heat can be provided using any suitable heat source, such as one or more lamps, such as one or more rapid thermal processing lamps, or via a heated pedestal (for example, a pedestal having resistive heating elements embedded therein or coupled thereto). In operation, the heat sources may enable independent temperature control of the substrate which is described in more detail below.

As shown in FIG. 1, processing chamber 110 may include window 162, such as a dome, and the plurality of lamps 176. The plurality of lamps 176 may be disposed between the window 162 and a bottom wall of the processing chamber 110. The plurality of lamps 176 may be positioned in an array. The plurality of lamps 176 can be arranged in a plurality of concentric rings surrounding a center of the processing chamber 110. The plurality of lamps 176 may include 100 or more lamps, and may include 200 or more lamps, such as from 200 lamps to 500 lamps, such as from 200 lamps to 300 lamps, such as 240 lamps, such as from 300 lamps to 400 lamps, such from 400 lamps to 500 lamps, or such as 400 lamps. The power of each of the plurality of lamps 176 may be from 400 W to 1000 W, such as from 500 W to 800 W, such as from 500 W to 600 W, such as from 600 W to 700 W, such as 645 W, or such as from 700 W to 800 W. A distance from the plurality of lamps 176 to the substrate may be about 50 mm or less, such as from about 5 mm to about 50 mm, such as from about 5 mm to about 20 mm, such as about 12.5 mm, such as from about 20 mm to about 50 mm, or such as about 36.5 mm.

A controller (not shown) may be coupled to the processing chamber 110, and may be used to control chamber processes described herein including controlling the plurality of lamps 176. The substrate support 112 may be disposed between a separation grid 116 and the window 162. A plurality of sensors (not shown) can be disposed proximate one or more of the lamps 176 and/or the substrate support 112 for measuring the temperature within the processing chamber 110. The plurality of sensors can include one or more infrared pyrometers or miniature pyrometers. In embodiments, the one or more pyrometers may include 2, 3, or 4 pyrometers. In embodiments, the pyrometers may have a wavelength of 3.3 μm, although in general, commercial pyrometer wavelengths typically vary from about 0.5 μm to about 14 μm. In embodiments, the pyrometers are bottom pyrometers, meaning the pyrometers are positioned below the substrate such as proximate the plurality of lamps 176.

The substrate support 112 may be coupled with a shaft 165. The shaft may be connected to an actuator 178 that may provide rotational movement of the shaft and substrate support (about an axis A). Actuator 178 may additionally or alternatively provide height adjustment of the shaft 165 during processing.

The substrate support 112 may include lift pin holes 166 disposed therein. The lift pin holes 166 may be sized to accommodate a lift pin 164 for lifting of the substrate 114 from the substrate support 112 either before or after a deposition or treatment process is performed. The lift pins 164 may rest on lift pin stops 168 when the substrate 114 is lowered from a processing position to a transfer position.

A plasma can be generated in plasma source 120 (for example, in a plasma generation region) by induction coil 130 and plasma effluents may flow from the plasma source 120 to the surface of substrate 114 through holes 126 provided in a separation grid 116 that separates the plasma source 120 from the processing chamber 110 (a downstream region).

The plasma source 120 may include a dielectric sidewall 122. The plasma source 120 may include a top plate 124. The dielectric sidewall 122 and top plate 124, integrated with a gas injection insert 140 may define a plasma source interior 125. Dielectric sidewall 122 may include any suitable dielectric material, such as quartz. An induction coil 130 may be disposed proximate (for example, adjacent) the dielectric sidewall 122 about the plasma source 120. The induction coil 130 may be coupled to an RF power generator 134 through any suitable matching network 132. Feed gases may be introduced to the plasma source interior from a gas supply 150. When the induction coil 130 is energized with RF power from the RF power generator 134, a plasma may be generated in the plasma source 120. In some embodiments, RF power may be provided to induction coil 130 at about 1 kW to about 15 kW, such as about 3 kW to about 10 kW. Induction coil 130 may ignite and sustain a plasma in a wide pressure and flow range. In some embodiments, the plasma processing apparatus 100 may include a grounded Faraday shield 128 to reduce capacitive coupling of the induction coil 130 to the plasma.

To increase efficiency, the plasma processing apparatus 100 may include gas injection insert 140 disposed in the plasma source interior 125. The gas injection channels 151 may provide the process gas to the plasma source interior 125 through an active zone 172, where a reaction between hot electrons and the feed gas may occur due to enhanced confinement of hot electrons. An enhanced electron confinement region or an active zone 172 may defined by sidewalls of gas injection insert and the vacuum tube in radial direction and by the edge of the surface 18 of the insert from the bottom in vertical direction. The active zone 172 may provide an electron confinement region within the plasma source interior 125 for efficient plasma generation and sustaining. The gas injection channels 151 can be narrow and prevent plasma spreading from the chamber interior into the gas injection channels 151. Gas injection channels 151 can be about 1 mm in diameter or greater, such as about 10 mm or greater, or about 1 mm to about 10 mm. The gas injection insert 140 may force the process gas to be passed through the active zone 172 where plasma may be formed.

The capabilities of the gas injection insert 140 to improve efficiency of the plasma processing apparatus 100 may be independent of the material of the gas injection insert 140 as long as the walls that are in direct contact with radicals are made of material with a low recombination rate for the radicals. For instance, in some embodiments, the gas injection insert 140 can be made from a metal, such as an aluminum material, with a coating configured to reduce surface recombination. Alternatively, the gas injection insert 140 can be a dielectric material, such as a quartz material, or an insulative material.

The induction coil 130 may be aligned with the active region in such a way that the top turn of the coil is above the surface 180 of the gas injection insert 140 and operates substantially in the active region of the inner volume, while the bottom turn of the coil is below surface 180 and operates substantially outside the active region. The center of the coil may be substantially aligned with the surface 180. Within these boundaries, one can adjust the coil position for a desired performance. Alignment of the coil with surface 180 may provide improved source efficiency, namely controlled generation of desired chemical species for plasma processes and delivering them to the substrate with reduced or eliminated losses. For example, plasma sustaining conditions (balance between local generation and loss of ions) might not be the best for generating species for a plasma process. Regarding delivery of the species to the substrate, efficiency can depend on the volume and wall recombination of these particular species. Hence, control of the alignment of the coil with surface 180 may provide control of the source efficiency for a plasma process.

In some embodiments, a coil has a short transition region near the leads, and the remainder of the coil turns are parallel to the surface 180. In other embodiments, a coil is helical, but one can always define the top and the bottom turn of the coil. In some embodiments, a coil can have 2-5 turns.

In some embodiments, surface 180 may be aligned with a portion of induction coil 130 (for example, coil loop 182) along axis 184 by utilizing a suitably sized gas injection insert 140 (and top plate 124, which may be a preformed part of the gas injection insert 140) to form the plasma source 120. Alternatively, surface 180 can be movable along a vertical direction V₁ relative to plasma source 120 while a remainder portion of gas injection insert 140 is static (for example, fixed) as part of plasma source 120, in order to provide alignment of surface 180 with a portion of induction coil 130. For example, a mechanism 170 can be coupled with any suitable portion of gas injection insert 140 to adjust a position of surface 180 such that a portion of gas injection insert 140 having a first length (L₁) is adjusted to a second length (L₂). Mechanism 170 can be any suitable mechanism, such as an actuator, for example a motor, electric motor, stepper motor, or pneumatic actuator. In some embodiments, a difference in length from L₁ to L₂ is about 0.1 cm to about 4 cm, such as about 1 cm to about 2 cm.

Additionally or alternatively, the gas injection insert 140 can be coupled to a mechanism (such as mechanism 170), and mechanism 170 may be configured to move the entirety of gas injection insert 140 vertically (for example, along a vertical direction V₁ relative to plasma source 120), in order to align surface 180 with a portion of induction coil 130. Spacers (not shown) can be used to fill gap(s) between gas injection insert 140 and another portion of plasma source 120 (such as between top plate 124 and dielectric sidewall 122) that were formed by moving the insert vertically. The spacers may be formed from, for example, a ceramic material, such as a quartz.

In general, positioning the induction coil 130 center above surface 180 may increase the efficiency of ionization and dissociation, but may reduce the transport efficiency of these species to the substrate, as many of the species may recombine on the walls of the narrow active region. Positioning the induction coil 130 below surface 1380 may improve plasma delivery efficiency, but may decrease plasma generation efficiency.

Separation grid 116 may be configured to separate a processing chamber 110 area from plasma charged particles (ions and electrons), which recombine on the grid, so that only neutral plasma species can pass through the grid into the processing chamber 110. The holes in the bottom section of the separation grid 116 may have various different patterns (for example, uniform or nonuniform). In some embodiments, separation grid 116 may be formed of aluminum, anodized aluminum, quartz, aluminum nitride, aluminum oxide, tantalum, tantalum nitride, titanium, titanium nitride, or combination(s) thereof. For example, AlN can be beneficial for flux of nitrogen radicals, whereas conventional separation grids are more prone to nitrogen radical recombination. Similarly, aluminum oxide can provide flux of oxygen or hydrogen radicals, whereas conventional separation grids are more prone to their recombination. In some embodiments, separation grid 116 may include a plurality of holes. The plurality of holes may be disposed through the separation grid (for example, the holes may traverse the thickness of the separation grid). The plurality of holes may have an average diameter that is from about 4 mm to about 6 mm. In some embodiments, each hole of the plurality of holes has a diameter that is from about 4 mm to about 6 mm. In some embodiments, the separation grid 116 has a thickness that is from about 5 mm to about 10 mm, which defines the hole length. A ratio of the grid thickness to the average diameter of the plurality of holes may be greater than about 1, such as about 1 to about 3.

Exhaust 192 may be coupled with a sidewall of processing chamber 110. In some embodiments, the exhaust 192 may be coupled with a bottom wall of the processing chamber 110 to provide azimuthal independence (for example, if not rotating pedestal). If lamps are rotating, the exhaust 192 can be coupled with the sidewall, since rotation mitigates azimuthal dependence.

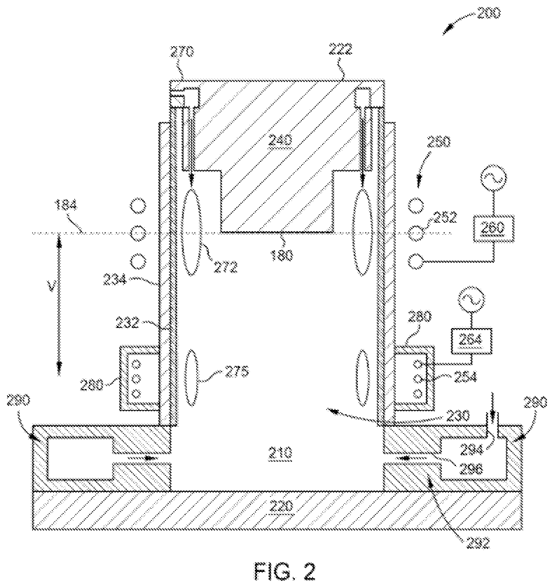

Various features of ICP sources and plasma processing apparatus will now be described with reference to FIGS. 2-5. Plasma processing apparatus of FIGS. 2-5 may be constructed in a similar manner to plasma processing apparatus 100 of FIG. 1 and may operate in a manner described above for plasma processing apparatus 100. It will be understood that the components of plasma processing apparatus FIGS. 2-5 may also be incorporated into any other suitable plasma processing apparatus in alternative example embodiments.

As shown in FIG. 2, plasma processing apparatus 200 may include a processing chamber 220 which has a separation grid (not shown) disposed therein. The plasma processing apparatus 200 may include a plasma source 222 along a vertical direction V. A substrate may be positioned in the processing chamber directly below the grid and some distance from the grid. Neutral particles from a plasma source interior 230 may flow downward through separation grid toward the substrate in the processing chamber 220, and the neutral particles may contact the substrate to perform a process, for example, a surface treatment process.

A plurality of induction coils 250 may be disposed at a different position along the vertical direction V on plasma source 222, for example, such that the induction coils (for example, induction coil 252 and 254) are spaced from each other along the vertical direction V along plasma source 222. For example, the induction coils 250 may include a first induction coil (peripheral induction coil 252) and a second induction coil (center induction coil 254). The first induction coil (peripheral induction coil 252) may be positioned at a first vertical position along a vertical surface of a dielectric sidewall 232. Second induction coil (center induction coil 254) may be positioned at a second vertical position along a vertical surface of the dielectric sidewall 232. The first vertical position may be different from the second vertical position. For instance, the first vertical position may be above the second vertical position. In some embodiments, a portion of the first induction coil (peripheral induction coil 252) may be substantially aligned with a surface 180 of the insert as was described above. The second induction coil (center induction coil 254) may be disposed at a bottom (for example, lower) portion of the plasma source. The second induction coil may include magnetic field concentrator(s) 280, allowing a placement of the coil in the bottom of the plasma source, as shown in FIG. 2. The use of magnetic field concentrator(s) 280 may increase efficiency of the plasma generation at the bottom of the source and significantly increases the radial control near the substrate (as compared to the absence of magnetic field concentrators). In some embodiments, the center induction coil 254 may be disposed at a bottom ⅓ height, such as a bottom ¼ height, of the plasma source 222.

The induction coils 250 may be operable to generate (or modify) an inductive plasma within plasma source interior 230. For example, the plasma processing apparatus 200 may include a first radio frequency power generator 262 (for example, RF generator and matching network) coupled with the peripheral induction coil 252. The center induction coil 254 may be coupled to a second radio frequency power generator 264 (for example, RF generator and matching network). The frequency and/or power of RF energy applied by the first radio frequency power generator 262 to the first induction coil (peripheral induction coil 252) and the second radio frequency power generator 264 to the second induction coil (center induction coil 254), respectively, can be independent in order to better control process parameters of a surface treatment process.

For example, frequency and/or power of RF energy applied by the second radio frequency power generator 264 can be less than the frequency and/or power of RF energy applied by the first radio frequency power generator 262. The first radio frequency power generator 262 may be operable to energize the peripheral induction coil 252 to generate the inductive plasma in the plasma source interior 230. In particular, the first radio frequency power generator 262 may energize peripheral induction coil 252 with an alternating current (AC) of radio frequency (RF) such that the AC induces an alternating magnetic and electric fields inside the volume near peripheral induction coil 252 that heats electrons to generate the inductive plasma. In some embodiments, RF power may be provided to the peripheral induction coil 252 at about 1 kW to about 15 KW, such as about 3 kW to about 15 kW. The peripheral induction coil 252 may ignite and sustain a plasma in a wide pressure and flow range. The second radio frequency power generator 264 may be operable to energize center induction coil 254 to generate and/or modify plasma in plasma source interior 230. In particular, the second radio frequency power generator 264 may energize the center induction coil 254 with an alternating current (AC) of radio frequency (RF) such that inductive RF electric field inside the volume adjacent to the center induction coil 254 accelerates electrons to generate plasma. In some embodiments, RF power may be provided to center induction coil 254 at about 0.5 kW to about 6 kW, such as about 0.5 kW to about 3 KW. The center induction coil 254 may modify the plasma density in the plasma processing apparatus 200. For example, the center induction coil 254 can tune the radial profile of the plasma to promote additional plasma uniformity moving toward a substrate in the processing chamber 220. Since the peripheral induction coil 252 may be further away from a substrate during use than the center induction coil 254, the plasma and radicals generated by the peripheral induction coil 252 can promote a dome shaped profile near the substrate, and the center induction coil 254 can flatten (or even raise the edge) the dome-shaped plasma profile as plasma approaches the substrate.

A dielectric sidewall 232 may be positioned between induction coils 250 and plasma source 222. The dielectric sidewall 232 may have a generally cylindrical shape. An electrically grounded Faraday shield 234 may be made of metal and/or may be positioned between the induction coils 250 and the dielectric sidewall 232. The Faraday shield 234 may have a cylindrical shape and may be disposed about the dielectric sidewall 232. The grounded faraday shield 234 may extend the length of the plasma source 222. The dielectric sidewall 232 may contain plasma within plasma source interior 230 allowing RF fields from induction coils 250 to pass through to the plasma source interior 230, and the grounded Faraday shield 234 may reduce capacitive coupling of the induction coils 250 to the plasma within the plasma source interior 230. In some embodiments, the Faraday shield 234 can be a metal cylinder having slots perpendicular to the coil direction. The vertical slots may be in the area of the coil (for example, adjacent the coil), while at least one vertical end of the coil (above or below the coil) may have a complete current path around the cylinder. A Faraday shield may have any suitable thickness, and/or the slots may have any suitable shape. Near the coil(s), the slots can be relatively narrow (for example, about 0.5 cm to about 2 cm) and substantially vertical, even when utilizing a helical coil.

As noted above, each induction coil 250 may be disposed at a different position along the vertical direction V on the plasma source 222 adjacent a vertical portion of a dielectric sidewall of the plasma source 222. In this way, each induction coil 250 can be operable to generate (or modify) a plasma in a region adjacent to the coil along the vertical surface of the dielectric sidewall 232 of the plasma source 222.

In some embodiments, the plasma processing apparatus 200 may include one or more peripheral gas injection ports 270 disposed through a gas injection insert 240 of the plasma source 222, radially outward of the gas injection insert 240. The peripheral gas injection port 270 and a side shape of the insert may be operable to inject process gas at the periphery of the plasma source interior 230, directly into active plasma generation region adjacent the vertical surface of the dielectric sidewall 232. For example, there may be greater than 20 (for example, between 70 and 200) vertical injection holes disposed through gas injection insert 240. For instance, the first induction coil (peripheral induction coil 252) can be operable to generate a plasma in region 272 proximate a vertical surface of the dielectric sidewall 232. The second induction coil (center induction coil 254) can be operable to generate or modify a plasma present in region 275 proximate a vertical surface of the dielectric sidewall 232. The gas injection insert 240, in some embodiments, can further define an active region for generation of the plasma in the plasma source interior 230 adjacent the vertical surface of the dielectric sidewall 232. A top portion of a gas injection insert of the present disclosure can have a diameter that is from about 10 cm to about 15 cm. A bottom portion of a gas injection insert of the present disclosure can have a diameter that is from about 7 cm to about 10 cm.

Plasma processing apparatus 200 can have an edge gas injection port 290 configured to introduce the same or different gas to volume 210 as the peripheral gas injection port 270 provides to plasma source interior 230. Edge gas injection port 290 may be coupled with the processing chamber 220 and may be a top plate of the processing chamber 220. Edge gas injection port 290 may include a plenum 292 (which may be circular) to which gas is introduced through inlet 294. Gas flows from the plenum 292 through one or more openings 296 to the volume 210. The edge gas injection port 290 can provide fine tuning of the plasma chemistry near the edge of a substrate, and/or improve plasma uniformity at the substrate. For example, the edge gas injection port 290 can provide modification of the flow (same gas), and/or modification of chemistry (chemical reaction between plasma radicals and new feed gas or different gases).

Plasma processing apparatus 200 may have improved source tunability relative to known plasma processing apparatus. For example, the induction coils 250 can be positioned in two locations along the vertical surface of the dielectric sidewall 232 such that functions of the peripheral induction coil 252 proximate to the active plasma generation region are plasma ignition and sustaining in the plasma source interior 230, and functions of the center induction coil 254 placed at the bottom of the source allow the advantageous source tunability. The low positioning of the second coil is possible due to the use of magnetic field concentrator(s) 280, which may provide coupling of the coil to plasma rather than to surrounding metal (for example, edge gas injection port 290). In such a manner, a treatment process performed with the plasma processing apparatus 200 on a substrate may be more uniform.

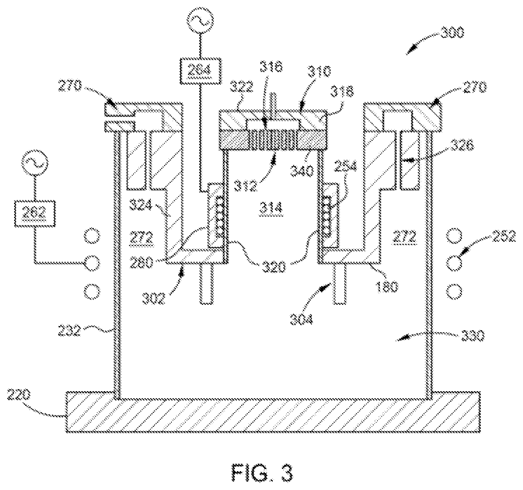

FIG. 3 is a schematic cross-sectional view of a plasma processing apparatus 300. The plasma processing apparatus 300 may include a plasma source 322 and a processing chamber 220. The plasma source 322 may include gas injection insert 302 having a peripheral gas injection port 270 and a center gas injection port 310. The center gas injection port 310 may be formed by a top plate 318 and a bottom plate 340 forming a plenum 316. The bottom plate 340 may have a plurality of holes (throughholes) 312 to enable the center gas injection port 310/gas injection insert 302 to have a plurality of the holes (throughholes) 312 for providing process gas into center process region 314. The dimensions of center process region 314 may be provided by portions of gas injection insert 302, namely center gas injection port 310 and sidewall 320. The sidewall 320 may have a cylindrical shape and may be a dielectric material. For example, the sidewall 320 may be formed from quartz or alumina. The dimensions of region 272 may be provided by dielectric sidewall 232 and gas injection insert 302, namely peripheral gas injection port 270 and sidewall 324. The sidewall 324 (and gas injection insert 302 in general) can have a cylindrical shape. The sidewall 324 surface material can be a dielectric material or a metal. For example, the sidewall 324 may be formed from aluminum and may be covered with quartz, or alumina, or have bare or anodized aluminum surface. In addition, a first Faraday shield (not shown) can be disposed between the peripheral induction coil 252 and the dielectric sidewall 232. Likewise, a second Faraday shield (not shown) can be disposed between the center induction coil 254 and the sidewall 320. In some embodiments, sidewall 320 may be quartz or ceramic and/or may have a thickness that is from about 2.5 mm to about 5 mm.

A flow rate of process gas provided by the peripheral gas injection port 270 via a conduit 326 to the region 272 can be greater than a flow rate of process gas provided by center gas injection port 310 to the center process region 314. In some embodiments, a ratio of flow rate of process gas provided by the peripheral gas injection port 270 to a flow rate of process gas provided by center gas injection port 310 may be about 2:1 to about 20:1, such as about 5:1 to about 10:1. Providing a higher flow rate to the region 272 than a flow rate to the center process region 314 may provide improved center-edge uniformity of a plasma at a substrate surface of a substrate present in the processing chamber 220.

The plasma processing apparatus 300 may further include the peripheral induction coil 252 and the center induction coil 254. An RF power provided by peripheral induction coil 252 can be greater than an RF power provided by the center induction coil 254. In some embodiments, a ratio of RF power provided by peripheral induction coil 252 to RF power provided by the center induction coil 254 may be about 2:1 to about 20:1, such as about 3:1 to about 10:1, or about 5:1. If the center coil is not energized, the secondary plasma source may serve as auxiliary gas injection that reduces fluxes of radicals and ions/electrons created by the peripheral induction coil 252 toward the center of the substrate. Because plasma density is typically higher at a center of a substrate during conventional plasma processes, providing a greater RF power to the center induction coil 254 than RF power provided to the peripheral induction coil 252 may promote increased plasma density at an edge portion(s) of the substrate, improving plasma uniformity. Plasma separator(s) 304 (cylindrical protrusions) between central and edge areas may improve the capability of independent central-edge plasma control.

The peripheral induction coil 252 and the center induction coil 254 may be operable to generate (or modify) an inductive plasma within plasma source interior 330. For example, the plasma processing apparatus 300 may include a first radio frequency power generator 262 (for example, RF generator and matching network) coupled with the peripheral induction coil 252. The center induction coil 254 may be coupled to a second radio frequency power generator 264 (for example, RF generator and matching network). The frequency and/or power of RF energy applied by the first radio frequency power generator 262 to the peripheral induction coil 252 and the second radio frequency power generator 264 to the center induction coil 254, respectively, can be adjusted to be the same or different to control process parameters of a substrate treatment process.

For example, frequency and/or power of RF energy applied by the second radio frequency power generator 264 can be less than the frequency and/or power of RF energy applied by the first radio frequency power generator 262. The first radio frequency power generator 262 may be operable to energize peripheral induction coil 252 to generate the inductive plasma in plasma source interior 330. In particular, the first radio frequency power generator 262 may energize the peripheral induction coil 252 with an alternating current (AC) of radio frequency (RF) such that the AC induces an alternating magnetic field inside the peripheral induction coil 252 that heats a gas to generate the inductive plasma. In some embodiments, RF power is provided to the peripheral induction coil 252 at about 1 kW to about 15 KW, such as about 3 kW to about 10 kW.

The second radio frequency power generator 264 may be operable to energize the center induction coil 254 to generate and/or modify an inductive plasma in the center process region 314 of the plasma source 322. In particular, the second radio frequency power generator 264 may energize the center induction coil 254 with an alternating current (AC) of radio frequency (RF) such that the AC induces an alternating magnetic field inside the center induction coil 254 that heats a gas to generate and/or modify the inductive plasma. In some embodiments, RF power may be provided to the center induction coil 254 at about 0.3 kW to about 3 kW, such as about 0.5 kW to about 2 kW. The center induction coil 254 may modify the plasma in the plasma processing apparatus 300. For example, the center induction coil 254 can tune the radial profile of the plasma to promote additional plasma uniformity moving toward a substrate in the processing chamber 220.

In some embodiments, the plasma processing apparatus 300 may include a peripheral gas injection port 270 operable to inject process gas at the periphery of the region 272 along a vertical surface of the dielectric sidewall 232, defining active plasma generation region(s) adjacent the vertical surface of the dielectric sidewall 232. For instance, the peripheral induction coil 252 can be operable to generate a plasma in the region 272 proximate a vertical surface of the dielectric sidewall 232. The center induction coil 254 can be operable to generate and/or modify a plasma present in a center process region 314 proximate a vertical surface of the sidewall 320. The gas injection insert 302, in some embodiments, can further define an active region for generation of the plasma in the plasma source interior adjacent the vertical surface of the dielectric sidewall 232 and the vertical surface of the sidewall 320.

In practice, the substrate can be provided some overlap of the process plasma formed in the center process region 314 with the process plasma formed in the region 272. Overall, peripheral gas injection port 270/center gas injection port 310 and peripheral induction coil 252/center induction coil 254 can provide improved plasma and process uniformity (center-to-edge plasma control) for treating a substrate with a plasma. To enhance center-to-edge process control, the gas injection insert 302 may include a plasma separator(s) 304. The plasma separator(s) 304 may be a uniform cylindrical separator coupled with (for example, disposed along) surface 180.

In addition, in embodiments where the process gas provided by center gas injection port 310 is different than process gas provided by the peripheral gas injection port 270, new plasma chemistries may be obtained as compared to conventional plasma processes using a conventional plasma source. For example, advantageous processing of substrates may be provided, which cannot be obtained in conventional plasma processing. For example, a unique mix of plasma can be created if one mixes a plasma generated flow of radicals and excited species (for example, some embodiments of region 272) with a flow of different plasma rich on different kind of plasma species, for example, different radicals. In addition, formation of these unique plasma chemistries can be obtained in embodiments utilizing alignment of the surface 180 with a portion of the peripheral induction coil 252, for example, as described above.

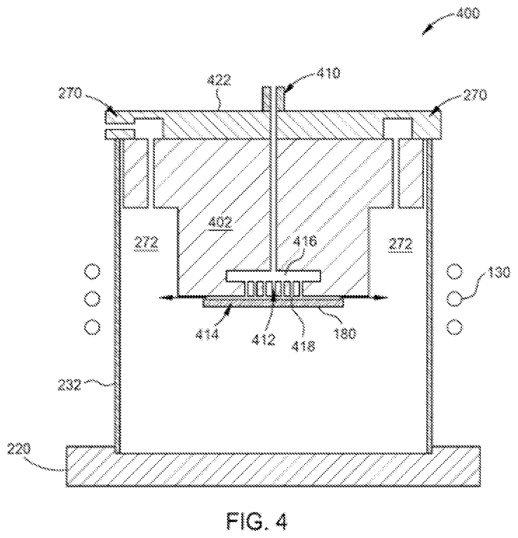

FIG. 4 is a schematic cross-sectional view of a plasma processing apparatus 400. The plasma processing apparatus 400 may include a plasma source 422. The plasma source 422 may include a gas injection insert 402, which can be integrated with the top cover, a peripheral gas injection port 270, and a center gas injection port 410. The center gas injection port 410 may be disposed within the gas injection insert 402 to fluidly couple the center gas injection port 410 with a gas distribution plenum 416 of gas injection insert 402. The gas distribution plenum 416 may provide an increased diameter (as compared to a diameter of the center gas injection port 410) for a process gas to distribute uniformly before the process gas enters the exhaust region between the bottom of the gas injection insert 402 and the platform 414. Once the gas is provided through holes 412, the platform 414 may provide a second gas distribution plenum and may promote an outward flow of the gas to a periphery (for example, into regions 272) of the plasma source 422. In some embodiments, the material to form the holes 412 may be absent and a larger plenum may be formed. The platform 414 can be coupled with the gas injection insert 402 via a plurality of screws or bolts (not shown). The platform 414 can be made of quartz or ceramic. The platform 414 can have any suitable design, which allows different materials. The outward/sideways flow of gas promoted by the platform 414 can affect the flow profile of gas/plasma to a substrate during processing, improving center-to-edge uniformity, as compared to conventional plasma process apparatus. In addition, this outward flow of the gas to a region adjacent to a plasma generation region (for example, region 272) of the plasma source 422 provides benefits. Because high plasma density can be created in region 272 adjacent to the top part of the induction coil 130, the electric field does not penetrate far away from the coil, so the gas from the center gas injection port 410, gas distribution plenum 416, and platform 414 does not experience a lot of ionization or dissociation, but the gas interacts chemically with high density radicals and ions created in the region 272. Both radicals and ions are active chemically and interact with a new feed gas from the center gas injection port 410, gas distribution plenum 416, and platform 414. The new feed gas, radicals, and ions may create new plasma chemistries as compared to conventional plasma sources using a plasma processing chamber. For example, a unique mix of plasma can be created if one mixes a plasma generated flow of radicals and excited species (for example, some embodiments of region 272) with a new flow of gas that does not pass through the region 272 with hot electrons (for example, the process gas provided by center gas injection port 410 and platform 414/region 418). For example, one can mix flow of H⁺ and H⁻ radicals obtained in plasma from the H₂ feed gas (for example, from gas provided by the peripheral gas injection port 270) with a flow of oxygen O₂ (for example, from gas provided by center gas injection port 410), where one can significantly increase fraction of HO₂, HO, H₂O₂, and other non-equilibrium molecules, etc. in the region adjacent to region 272 related to the induction coil 130. In addition, formation of these unique plasma chemistries can be obtained in embodiments utilizing alignment of surface 180 edge with a portion of the induction coil 130, for example, as described above.

In some embodiments, a ratio of flow rate of process gas provided by the peripheral gas injection port 270 to a flow rate of process gas provided by the center gas injection port 410 is about 20:1 to about 1:20, such as about 10:1 to about 1:10, such as about 2:1 to about 1:2, such as about 1.2:1 to about 1:1.2, or about 1:1. Such flow rates may provide a stoichiometry (for example, substantially equimolar amounts) of the different process gases to provide desired densities of chemical species in a plasma formed in regions 272.

In addition, the outward/sideways flow provided by center gas injection port 410 and platform 414/region 418 can modify flow patterns within the plasma source 422 affecting delivery profile of radicals to the substrate. For example, in embodiments where the process gas provided by the center gas injection port 410 is substantially the same as the process gas provided by the peripheral gas injection port 270, more plasma flow may be promoted toward an edge of a substrate, improving the center-edge plasma profile (for example, uniformity of plasma provided to the substrate).

In addition, in embodiments where the process gas provided by the center gas injection port 410 is different than process gas provided by the peripheral gas injection port 270, new plasma chemistries may be obtained as compared to conventional plasma processes using a conventional plasma source. For example, advantageous processing of substrates may be provided, which cannot be obtained in conventional plasma processing. For example, a unique mix of plasma can be created if one mixes a plasma generated flow of radicals and excited species (for example, some embodiments of region 272) with a new flow of gas that does not pass through the plasma region with hot electrons. For example, one can mix flow of N-radical obtained in plasma from the N₂ feed gas with a flow of Nitrogen (N₂), hydrazine, and/or NH₃, where one can generate a large number of different radicals like NH and/or NH₂ molecules in a region of plasma processing apparatus 400 that is downstream of regions 272. In addition, formation of these unique plasma chemistries can be obtained in embodiments utilizing alignment of surface 180 with a portion of the peripheral induction coil 252, for example, as described above.

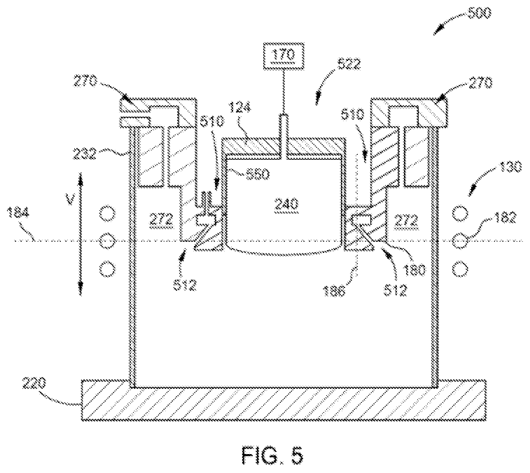

FIG. 5 is a schematic cross-sectional view of a plasma processing apparatus 500.

Plasma processing apparatus 500 may include plasma source 522 and processing chamber 220. The plasma source 522 may include a gas injection insert 240, a peripheral gas injection port 270, a center gas injection port 510, and top plate 124. The center gas injection port 510 can be disposed proximate (for example, adjacent) a wall 550. Center gas injection may include a center gas injection port 510 having a generally cylindrical plenum/manifold and a plurality of angled outlets 512 uniformly spread along the plenum. The gas injection insert 240 can likewise have a generally cylindrical shape. The center gas injection port 510 may have an angled outlet 512 to promote outward/sideways flow of process gas provided by the center gas injection port 510 and angled outlets 512. The angled outlets 512 can have an angle that is from about 0 degree to about 90 degrees, such as about 30 degrees to about 60 degrees, such as about 45 degrees, relative to a vertical axis (such as vertical axis 186, which is parallel to an axial centerline of the plasma processing apparatus 500 and/or the axial centerline of the plasma source 522).

The outward/sideways flow of gas promoted by angled outlet 512 can affect the flow profile of gas/plasma to a substrate during processing, improving center-to-edge uniformity, as compared to conventional plasma process apparatus. In addition, because a high plasma density can be created in a region adjacent the induction coil 130 (and the electric field does not penetrate far away from the coil), new plasma chemistries can be obtained as compared to conventional plasma processes using a plasma processing chamber. For example, a unique mix of plasma can be created if one mixes a plasma generated flow of radicals and excited species (for example, some embodiments of region 272) with a new flow of gas that does not pass through the plasma region with hot electrons (for example, the process gas provided by the center gas injection port 510 and angled outlet 512). For example, one can mix flow of N-radicals obtained in plasma from the N₂ feed gas (for example, from gas provided by peripheral gas injection port 270) with a flow of N₂, hydrazine, and/or NH₃ (for example, from gas provided by center gas injection port 510), where one can generate molecular radicals like NH, NH₂ molecules, etc. in region 272 adjacent the induction coil 130. In addition, formation of these unique plasma chemistries can be obtained in embodiments utilizing alignment of induction coil 130 with surface 180, as described above.

In some embodiments, a ratio of flow rate of process gas provided by the peripheral gas injection port 270 to a flow rate of process gas provided by center gas injection port 510 may be about 2:1 to about 1:2, such as about 1.2:1 to about 1:1.2, or about 1:1. Such flow rates may provide a stoichiometry (for example, substantially equimolar amounts) of the different process gases to provide desired densities of chemical species in a plasma formed in regions 272.

In addition, the outward/sideways flow provided by center gas injection port 510 and angled outlets 512 can modify flow patterns within the plasma source 522 affecting delivery profile of radicals to the substrate. For example, in embodiments where the process gas provided by center gas injection port 510 is substantially the same as the process gas provided by peripheral gas injection port 270, more plasma flow may be promoted toward an edge of a substrate, improving the center-edge plasma profile (for example, uniformity of plasma provided to the substrate).

Furthermore, gas injection insert 240 of FIG. 5 may have a fixed edge at the surface 180, defining the active region that marks the axis 184 (or alignment level) for the induction coil 130. The induction coil 130 may be substantially aligned with surface 180 in such a way that the top turn of the coil is positioned above the axis 184 (surface 180), and the bottom turn is positioned below the edge. One may further adjust position of the coil within this range based on the process results. Alignment of coil vertical center with surface 180 may provide improved source efficiency, namely controlled generation of desired chemical species for plasma processes and delivering them to the substrate with minimum losses. For example, plasma sustaining conditions (balance between local generation and loss of ions) may not work well for generating species for a plasma process. Regarding delivery of the species to the substrate, efficiency can depend on the volume and wall recombination of these particular species. Hence, control of the alignment of the induction coil 130 with the surface 180 (edge) may provide control of the source efficiency for a plasma process.

In some embodiments, a bottom surface of gas injection insert 240 may be aligned with the surface 180 of the insert defining the active region for the coil (this alignment level is shown as axis 184) by utilizing a suitably sized gas injection insert 240 to form the plasma source 120. Alternatively, the bottom surface of the gas injection insert 240 can be made flexible using a movable central part as shown in FIG. 5 of the gas injection insert 240, while a remainder portion of gas injection insert 240 may be fixed as part of plasma source 120. For example, a mechanism 170 can be electronically coupled with the central part of gas injection insert 240 to adjust the central part such that the central part of gas injection insert 240 having a first position is adjusted to a second position. In some embodiments, a difference in position from the first position to the second position may be about 0.1 cm to about 10 cm, such as about 1 cm to about 2 cm. Mechanism 170 can be any suitable mechanism, such as an actuator, for example a motor, electric motor, stepper motor, or pneumatic actuator. Movement of the central part of the gas injection insert 240 by mechanism 170 may increase or decrease a space between the central part and top plate 124.

In general, moving the central part of the gas injection insert 240 downward along a vertical direction V will reduce the flow of active species toward the center of the substrate and thus decrease the process rate in the center vs. edge, while moving the central part upward will increase the process rate in the center vs. edge.

Although FIGS. 1-5 have been described independently, it is to be understood that one or more embodiments from one figure may be beneficially incorporated with one or more embodiments of a different figure. For example, gas injection insert 140 of FIG. 1 or gas injection insert 240 of FIG. 2 may be gas injection insert 302 of FIG. 3, gas injection insert 402 of FIG. 4, or the configuration of gas injection insert 240 and center gas injection port 510 of FIG. 5. As another non-limiting example, the edge gas injection port 290 may be included as an embodiment with the plasma processing apparatus 300 of FIG. 3, the plasma processing apparatus 400 of FIG. 4, and the plasma processing apparatus 500 of FIG. 5.

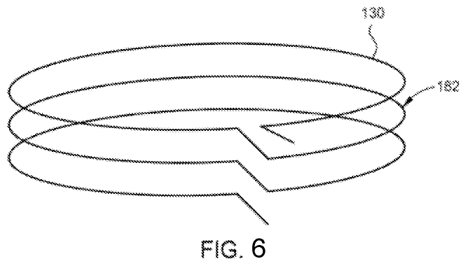

FIG. 6 illustrates an induction coil 130 that can be used with a plasma source. Induction coil 130 may include a plurality of coil loops including coil loop 182. As illustrated, the induction coil 130 may include 3 complete coils, but more or less coils are contemplated. For example, an induction coil may include 2-6 complete turns for RF frequency of 13.56 MHz. More turns may be utilized for lower RF frequency.

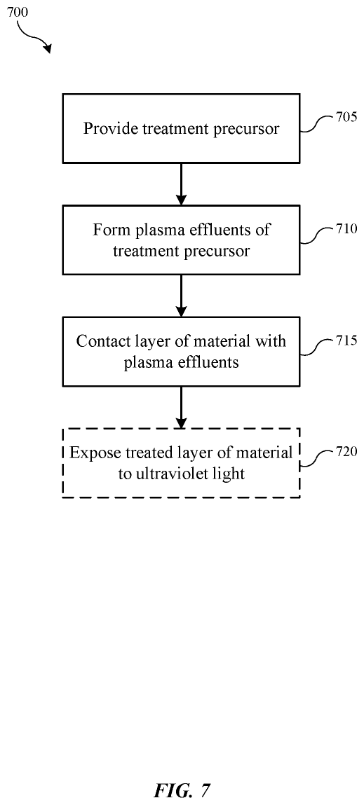

Any of the plasma processing apparatuses or processing chambers previously discussed may be utilized in some embodiments of the present technology for processing methods that may include formation or treatment of materials for semiconductor structures. It is to be understood that the chamber described is not to be considered limiting, and any chamber that may be configured to perform operations as described may be similarly used. FIG. 7 shows exemplary operations in a processing method 700 according to some embodiments of the present technology. The method 700 may be performed in a variety of processing chambers and on one or more mainframes or tools, including processing chambers described above. Method 700 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated.

Method 700 may include additional operations prior to initiation of the listed operations. For example, additional processing operations may include forming structures on a substrate, which may include both forming and removing material. For example, transistor structures, memory structures, or any other structures may be formed. Prior processing operations may be performed in the chamber in which method 700 may be performed, or processing may be performed in one or more other processing chambers prior to delivering the substrate into the semiconductor processing chamber or chambers in which method 700 may be performed. Regardless, method 700 may optionally include delivering a semiconductor substrate to a processing region of a semiconductor processing chamber, such as processing chamber 110 described above, any other processing chamber previously discussed, or other processing chambers that may include components as described above. The substrate may be deposited on a substrate support, which may be a pedestal such as substrate support 112, and which may reside in a processing region of the processing chamber.

A substrate on which several operations have been performed may be substrate including one or more layers of material deposited thereon. Substrate may be any number of materials used in semiconductor processing. The substrate material may be or include silicon, germanium, dielectric materials including silicon oxide or silicon nitride, metal materials, or any number of combinations of these materials. In embodiments, a layer of a silicon-containing material may be disposed on the substrate. The silicon-containing material may be a silicon-and-oxygen-containing material, a silicon-carbon-and-oxygen-containing material, or a silicon-carbon-oxygen-and-hydrogen-containing material. Additionally, multiple layers of silicon-containing material may be present and/or one or more features may be formed in the one or more layers of material. Features, if present, may be characterized by any shape or configuration. In some embodiments, the features may be or include a trench structure or aperture.

In some embodiments, method 700 may include optional treatment operations, such as a pretreatment, that may be performed to prepare a surface of substrate for treatment. Once prepared, method 700 may include providing one or more precursors to the semiconductor processing chamber housing the substrate at operation 705. The precursors may include one or more treatment precursors. Treatment precursors that may be used during the method 700 may include, but are not limited to, diatomic nitrogen (N₂), diatomic oxygen (O₂), ammonia (NH₃), argon (Ar), helium (He), or diatomic hydrogen (H₂), as well as any other diluents or carrier gases such as an inert gas or other gas delivered with the treatment precursor.

Inductively-coupled plasma effluents of the treatment precursor may be formed at operation 710. The plasma effluents may be formed within a plasma region that may be separated from a processing region via a separation grid, which may allow formation of the plasma effluents in a region remote from the substrate. For example, in some embodiments the inductively-coupled plasma effluents may be formed within the plasma region by applying plasma power to an induction coil as previously described.

The power applied during the treatment may be a higher power plasma, which may increase dissociation, and which may provide treatment plasma effluents with high radical density and high flux. Accordingly, in some embodiments a plasma power source may deliver a plasma power to the induction coil of greater than or about 1,000 W, and may deliver a power of greater than or about 1,500 W, greater than or about 2,000 W, greater than or about 2,500 W, greater than or about 3,000 W, greater than or about 3,500 W, greater than or about 4,000 W, greater than or about 4,500 W, greater than or about 5,000 W, greater than or about 5,500 W, greater than or about 6,000 W, or more. At plasma powers of less than, for example, 1,000 W, the radical density and flux of the plasma effluents may not be sufficient to treat the layer of the silicon-containing material on the substrate to increase desired mechanical properties of the material.

At operation 715, method 700 may include contacting the layer of the silicon-containing material with the inductively-coupled plasma effluents of the treatment precursor to produce a treated layer of the silicon-containing material. During operation 715, the inductively-coupled plasma effluents of the treatment precursor may diffuse into the layer of the silicon-containing material on the substrate. The internal energy from the inductively-coupled plasma effluents of the treatment precursor may modify the layer of the silicon-containing material to increase desired mechanical properties of the layer of the silicon-containing material. For example, the inductively-coupled plasma effluents of the treatment precursor may diffuse into the layer of the silicon-containing material on the substrate and densify the material while modifying bonds in the material.

In embodiments, the treatment at operation 715 may produce the treated layer of the silicon-containing material that may be characterized by an increased porosity and/or a reduced dielectric constant, as well as increased other mechanical properties, than the as-deposited material. Additionally, due to the densification, the treated layer of the silicon-containing material may be characterized by a second thickness less than a first thickness of the layer of the silicon-containing material. The first thickness of the layer of the silicon-containing material may be the thickness of the as-deposited material.

At optional operation 720, method 700 may include exposing the treated layer of the silicon-containing material to ultraviolet (UV) light to produce a cured layer of the silicon-containing material. Optional operation 720 may include directing energy in the form of UV light towards the substrate to cure the treated layer of the silicon-containing material on the substrate. In some embodiments, the exposure to UV light may be performed in the processing chamber used for the treatment of the layer of the silicon-containing material. In additional embodiments, the substrate with the treated layer of the silicon-containing material may be transferred to another semiconductor processing chamber where the exposure to UV light is performed.

In embodiments, the exposure to UV light at optional operation 720 may produce the cured layer of the silicon-containing material that may be characterized by a further increased porosity and/or a further reduced dielectric constant, as well as increased other mechanical properties, than the as-deposited material and/or the treated material.

The treatment at operation 715 and/or the exposure to UV light at optional operation 720 may be performed at substrate or pedestal temperatures greater than or about 150° C. Consequently, in some embodiments the treatment at operation 715 and/or the exposure to UV light at optional operation 720 may occur at temperatures greater than or about 200° C., greater than or about 250° C., greater than or about 300° C., greater than or about 350° C., greater than or about 400° C., greater than or about 450° C., or higher. Additionally, the temperature may be maintained at less than or about 500° C., which may meet thermal budget requirements. In embodiments, the temperature may be maintained at less than or about 450° C., less than or about 400° C., less than or about 350° C., less than or about 300° C., less than or about 250° C., less than or about 200° C., less than or about 150° C., or less.

The treatment at operation 715 and/or the exposure to UV light at optional operation 720 may be performed at a pressure of less than or about 500 Torr, such as less than or about 450 Torr, less than or about 400 Torr, less than or about 350 Torr, less than or about 300 Torr, less than or about 250 Torr, less than or about 200 Torr, less than or about 150 Torr, less than or about 100 Torr, less than or about 75 Torr, less than or about 50 Torr, less than or about 25 Torr, less than or about 10 Torr, less than or about 8 Torr, less than or about 6 Torr, less than or about 5 Torr, less than or about 4 Torr, less than or about 3 Torr, less than or about 2 Torr, less than or about 1 Torr, or less. Operation 715 and optional operation 720 may be performed at the same or similar process conditions. For example, the temperature and/or pressure may be maintained for both the treatment at operation 715 and the exposure to UV light at optional operation 720. Conversely, the temperature and/or pressure may be modified or adjusted between the operations of method 700.

Subsequent the treatment at operation 715 and/or the UV light exposure at optional operation 720, the treated and/or cured layer of the silicon-containing material may be characterized by increased mechanical properties. In embodiments, compared to the as-deposited material, the treated and/or cured layer of the silicon-containing material may be characterized by an increased refractive index (RI), a decreased methyl concentration, an increased amount of Si—C—Si and/or Si—O—Si crosslinking, as well as decreased dielectric constant, increased porosity, increased hardness, and/or increased Young's modulus.

In embodiments, the treated and/or cured layer of the silicon-containing material may be characterized by an RI of greater than or about 1.48, and may be characterized by an RI of greater than or about 1.49, greater than or about 1.50, greater than or about 1.51, greater than or about 1.52, greater than or about 1.53, greater than or about 1.54, greater than or about 1.55, greater than or about 1.56, greater than or about 1.57, greater than or about 1.58, greater than or about 1.59, or more.

The treated and/or cured layer of the silicon-containing material may be characterized by an atom (i.e., molecule) percentage of methyl groups (—CH₃) relative to silicon oxide (SiO) groups in the material as measured by the areas of infrared absorption peaks attributed to these groups. The treated and/or cured layer of the silicon-containing material may be characterized by a methyl concentration of less than or about 6%, and may be characterized by a methyl concentration of less than or about 5%, less than or about 4.5%, less than or about 4%, less than or about 3.5%, less than or about 3%, less than or about 2.5%, less than or about 2%, less than or about 1.5%, or less. The percentage of methyl concentration may be a unit area percentage obtained from infrared absorption peaks (e.g., comparing methyl area over SiO area).

Similarly, the treated and/or cured layer of the silicon-containing material may be characterized by an atom (i.e., molecule) percentage of Si—C—Si crosslinking relative to silicon oxide (SiO) groups in the material as measured by the areas of infrared absorption peaks attributed to these groups. The treatment at operation 715 and/or the exposure to UV light at optional operation 720 may increase Si—C—Si crosslinking in the material. In embodiments, the treated and/or cured layer of the silicon-containing material may be characterized by Si—C—Si crosslinking of greater than or about 0.4%, and may be characterized by Si—C—Si crosslinking of greater than or about 0.42%, greater than or about 0.44%, greater than or about 0.46%, greater than or about 0.48%, greater than or about 0.5%, greater than or about 0.52%, greater than or about 0.54%, greater than or about 0.56%, greater than or about 0.58%, greater than or about 0.6%, greater than or about 0.62%, or more. The percentage of Si—C—Si crosslinking may be a unit area percentage obtained from infrared absorption peaks (e.g., comparing Si—C—Si crosslinking area over SiO area).

In embodiments, the dielectric constant of the treated and/or cured layer of the silicon-containing material may be less than or about 4, and may be less than or about 3.8, less than or about 3.6, less than or about 3.5, less than or about 3.5, less than or about 3.4, less than or about 3.3, less than or about 3.2, less than or about 3.1, less than or about 3.0, less than or about 2.95, less than or about 2.9, less than or about 2.85, less than or about 2.8, less than or about 2.75, less than or about 2.7, less than or about 2.65, less than or about 2.6, less than or about 2.55, less than or about 2.5, or less.

The hardness of the treated and/or cured layer of the silicon-containing material may be greater than or about 2 GPa, and may be greater than or about 2.2 GPa, greater than or about 2.4 GPa, greater than or about 2.6 GPa, greater than or about 2.8 GPa, greater than or about 3 GPa, greater than or about 3.2 GPa, greater than or about 3.4 GPa, greater than or about 3.6 GPa, greater than or about 3.8 GPa, greater than or about 4 GPa, greater than or about 4.5 GPa, greater than or about 5 GPa, greater than or about 5.5 GPa, greater than or about 6 GPa, greater than or about 6.5 GPa, greater than or about 7 GPa, greater than or about 7.5 GPa, greater than or about 8 GPa, greater than or about 9 GPa, or more. Further, the Young's modulus of the treated and/or cured layer of the silicon-containing material may be greater than or about 4 GPa, greater than or about 4.5 GPa, greater than or about 5 GPa, greater than or about 5.5 GPa, or more.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a treatment precursor” includes a plurality of such precursors, and reference to “the layer of the silicon-containing material” includes reference to one or more materials and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing a treatment precursor to a processing region of a semiconductor processing chamber, wherein a substrate is housed within the processing region, and wherein the substrate comprises a layer of a silicon-containing material;
forming inductively-coupled plasma effluents of the treatment precursor; and
contacting the layer of the silicon-containing material with the inductively-coupled plasma effluents of the treatment precursor to produce a treated layer of the silicon-containing material, wherein the contacting reduces a dielectric constant of the layer of the silicon-containing material.

2. The semiconductor processing method of claim 1, wherein the treatment precursor comprises one or more of diatomic nitrogen (N₂), diatomic oxygen (O₂), ammonia (NH₃), argon (Ar), helium (He), or diatomic hydrogen (H₂).

3. The semiconductor processing method of claim 1, wherein the silicon-containing material comprises a silicon-and-oxygen-containing material, a silicon-carbon-and-oxygen-containing material, or a silicon-carbon-oxygen-and-hydrogen-containing material.

4. The semiconductor processing method of claim 1, wherein the inductively-coupled plasma effluents of the treatment precursor are formed at a plasma power of greater than or about 2,000 W.

5. The semiconductor processing method of claim 1, wherein the treated layer of the silicon-containing material is characterized by a dielectric constant of less than or about 2.9.

6. The semiconductor processing method of claim 1, wherein the contacting increases Si—C—Si crosslinking in the layer of the silicon-containing material, and wherein the treated layer of the silicon-containing material is characterized by Si—C—Si crosslinking of greater than or about 0.4%.

7. The semiconductor processing method of claim 1, wherein contacting the layer of the silicon-containing material with the inductively-coupled plasma effluents of the treatment precursor reduces a carbon content in the layer of the silicon-containing material.

8. The semiconductor processing method of claim 1, wherein a pressure within the processing region is maintained at less than or about 50 Torr.

9. The semiconductor processing method of claim 1, wherein a temperature within the processing region is maintained at greater than or about 150° C.

10. The semiconductor processing method of claim 9, further comprising:
exposing the treated layer of the silicon-containing material to ultraviolet light to produce a cured layer of the silicon-containing material.

11. A semiconductor processing method comprising:
providing a treatment precursor to a processing region of a semiconductor processing chamber, wherein a substrate is housed within the processing region, and wherein the substrate comprises a layer of a silicon-containing material;
forming inductively-coupled plasma effluents of the treatment precursor at a plasma power of greater than or about 2,000 W; and
contacting the layer of the silicon-containing material with the inductively-coupled plasma effluents of the treatment precursor to produce a treated layer of the silicon-containing material, wherein the contacting increases one or more mechanical properties of the layer of the silicon-containing material.

12. The semiconductor processing method of claim 11, wherein the silicon-containing material comprises a silicon-and-oxygen-containing material, a silicon-carbon-and-oxygen-containing material, or a silicon-carbon-oxygen-and-hydrogen-containing material.

13. The semiconductor processing method of claim 11, wherein the one or more mechanical properties comprise hardness, Young's modulus, dielectric constant, or porosity.

14. The semiconductor processing method of claim 11, wherein the treated layer of the silicon-containing material is characterized by a second thickness less than a first thickness of the layer of the silicon-containing material.

15. The semiconductor processing method of claim 11, further comprising:
exposing the treated layer of the silicon-containing material to ultraviolet light to produce a cured layer of the silicon-containing material, wherein the exposing reduces a methyl concentration in the layer of the treated layer of the silicon-containing material, and wherein the cured layer of the silicon-containing material is characterized by a methyl concentration of less than or about 4.5%.

16. The semiconductor processing method of claim 15, wherein the cured layer of the silicon-containing material is characterized by a dielectric constant of less than or about 2.85.

17. The semiconductor processing method of claim 15, wherein the cured layer of the silicon-containing material is characterized by a hardness of greater than or about 3 GPa.

18. A semiconductor processing method comprising:
providing a treatment precursor to a processing region of a semiconductor processing chamber, wherein a substrate is housed within the processing region, and wherein the substrate comprises a layer of a silicon-containing material;
forming inductively-coupled plasma effluents of the treatment precursor;
contacting the layer of the silicon-containing material with the inductively-coupled plasma effluents of the treatment precursor to produce a treated layer of the silicon-containing material; and
exposing the treated layer of the silicon-containing material to ultraviolet light to produce a cured layer of the silicon-containing material.

19. The semiconductor processing method of claim 18, wherein the treatment precursor comprises helium (He).

20. The semiconductor processing method of claim 18, wherein the cured layer of the silicon-containing material is characterized by a hardness of greater than or about 2 GPa.
